(19) United States
(12) Patent Application Publication
(10) Pub. No.: US 2020/0176302 A1
(43) Pub. Date: Jun. 4, 2020

(54) BUSHING PORTION AND A SUBSTRATE PROCESSING APPARATUS INCLUDING THE SAME

(71) Applicant: SAMSUNG DISPLAY CO., LTD., Yongin-si (KR)

(72) Inventors: Heesung LIM, Seoul (KR); Youngkweon KIM, Seoul (KR)

(21) Appl. No.: 16/584,098

(22) Filed: Sep. 26, 2019

(30) Foreign Application Priority Data
Nov. 29, 2018 (KR) 10-2018-0151207

(51) Int. Cl. H01L 21/687; H01L 21/67; H01L 51/00; B05D 3/06

(52) U.S. Cl. CPC H01L 21/68785; H01L 21/67017; H01L 51/5012; H01L 51/0026; B05D 3/067; H01L 21/67115

(57) ABSTRACT

A substrate processing apparatus may include a stage having a plane defined by a first direction and a second direction crossing each other, a pin arranged in an opening defined in the stage and extending in a third direction crossing the plane, and a bushing portion below the stage. The pin may be inserted in an insertion hole defined in the bushing portion, the insertion hole may overlap with the opening, and a first hole extending to the insertion hole in a direction parallel to the plane may be defined in the bushing portion.

### CROSS-REFERENCE TO RELATED APPLICATION

This application claims priority to and the benefit of Korean Patent Application No. 10-2018-0151207, filed on Nov. 29, 2018 in the Korean Intellectual Property Office, the entire content of which is hereby incorporated by reference.

### BACKGROUND

### 1. Field

Aspects of embodiments of the present disclosure relate to a bushing portion and a substrate processing apparatus including the same.

### 2. Description of the Related Art

An organic light emitting diode (OLED) display device has been attracting attention as a next generation flat panel display device because it provides excellent luminance and viewing angle characteristics, without a light source unit necessarily required for a liquid crystal display (LCD) device. Since there is no need for the light source unit, the OLED display device can be fabricated to be lighter and thinner than the LCD device. In addition, the OLED display device has other technical advantages (e.g., low power consumption, high luminance, and high response speed).

The OLED display device includes a plurality of light emitting elements, each of which includes an anode, an organic light emitting layer, and a cathode. In the case in which holes and electrons are injected into the organic light emitting layer through the anode and the cathode, respectively, excitons are produced in the organic light emitting layer, and light is emitted from the light emitting element due to transition of the excitons to a ground state.

To fabricate the organic light emitting layer on a substrate, the substrate is disposed in a process chamber. A plurality of pins is provided to be vertically movable through a plurality of openings defined in a stage. If the substrate is disposed on pins, the pins are moved downwardly to load the substrate on the stage. Thereafter, an ink is provided on the substrate and is hardened by an ultraviolet light to form the organic light emitting layer.

When the ultraviolet light emitted from an ultraviolet light lamp is irradiated onto the ink, the pins are also heated by the ultraviolet light to have a temperature higher than those of the substrate and the stage. That is, the irradiation of the ultraviolet light may lead to a difference in temperature between the pins and the substrate. The pins are in contact with a bottom surface of the substrate through the openings. Due to the difference in temperature between the pins and the substrate, a stain issue may occur at portions of the substrate in contact with the pins.

### SUMMARY

According to aspects of embodiments of the inventive concept, a bushing portion, which is configured to prevent or substantially prevent pins from causing a stain on a substrate in an ink hardening process, and a substrate processing apparatus including the same, are provided.

According to one or more embodiments of the inventive concept, a substrate processing apparatus includes a stage having a plane defined by a first direction and a second direction crossing each other, a pin arranged in an opening defined in the stage and extending in a third direction crossing the plane, and a bushing portion below the stage. The pin may be inserted in an insertion hole defined in the bushing portion, the insertion hole may overlap with the opening, and a first hole extending to the insertion hole in a direction parallel to the plane may be defined in the bushing portion.

According to one or more embodiments of the inventive concept, a bushing portion includes an insertion portion, a connecting portion below the insertion portion, and an air injection portion below the connecting portion and in which an insertion hole extending in an upward direction is defined. The upward direction may cross a plane defined by a first direction and a second direction crossing each other. The insertion hole may extend in the upward direction and may be defined in the connecting portion and the insertion portion, a first hole extending to the insertion hole in a direction parallel to the plane may be defined in the air injection portion, and the first hole may be supplied with a cooling air.

### BRIEF DESCRIPTION OF THE DRAWINGS

The inventive concept will be more clearly understood from the following description of some example embodiments, taken in conjunction with the accompanying drawings. The accompanying drawings represent some non-limiting, example embodiments as described herein.

FIG. 1 is a diagram illustrating a substrate processing apparatus according to an embodiment of the inventive concept.

FIG. 2 is a perspective view illustrating a stage and a supporting part of FIG. 1.

FIG. 3 is a perspective view illustrating a bushing portion of FIG. 1.

FIG. 4 is a side view of the bushing portion of FIG. 3, viewed in a first direction.

FIG. 5 is a cross-sectional view taken along the line I-I′ of FIG. 3.

FIG. 6 is a cross-sectional view taken along the line II-II′ of FIG. 4.

FIG. 7 is a cross-sectional view illustrating a bushing portion connected to a stage of FIG. 1 and a pin disposed in an opening.

FIGS. 8 to 10 are diagrams illustrating a substrate processing process performed using the substrate processing apparatus of FIG. 1.

FIG. 11 is a cross-sectional view illustrating a bushing portion connected to a stage of FIG. 10, a pin disposed in an opening, and a substrate disposed on the pin.

FIG. 12 is a diagram illustrating a flow of a cooling air flowing through an air injection portion of FIG. 10.

FIG. 13 is a cross-sectional view illustrating a portion of a substrate processing apparatus, in which a bushing portion is not disposed.

FIG. 14 is a cross-sectional view illustrating a pixel including an organic light emitting layer, which is fabricated by a substrate processing apparatus according to an embodiment of the inventive concept.

It should be noted that these figures are intended to illustrate the general characteristics of methods, structures, and/or materials utilized in certain example embodiments and to supplement the written description provided below. These drawings may not, however, be to scale and may not precisely reflect the structural or performance characteristics of any given embodiment, and should not be interpreted as defining or limiting the range of values or properties encompassed by embodiments. For example, the relative thicknesses and positioning of components, layers, regions, and/or structural elements may be reduced or exaggerated for clarity. The use of similar or same reference numerals in the various drawings is intended to indicate the presence of a similar or same element or feature.

### DETAILED DESCRIPTION

Some example embodiments of the inventive concept will now be described more fully with reference to the accompanying drawings, in which some example embodiments are shown. Embodiments of the inventive concepts may, however, be embodied in many different forms and should not be construed as being limited to the embodiments set forth herein; rather, these embodiments are provided so that this disclosure will be thorough and complete, and will fully convey the concept of the present invention to those of ordinary skill in the art. In the drawings, the thicknesses of layers and regions may be exaggerated for clarity. Like reference numerals in the drawings denote like elements, and, thus, their repeated description may be omitted.

It is to be understood that when an element is referred to as being “connected” or “coupled” to another element, it may be directly connected or coupled to the other element or one or more intervening elements may be present. In contrast, when an element is referred to as being “directly connected” or “directly coupled” to another element, there are no intervening elements present. Other terms used to describe the relationship between elements or layers should be interpreted in a like fashion (e.g., “between” versus “directly between,” “adjacent” versus “directly adjacent,” “on” versus “directly on”). Like numbers indicate like elements throughout. As used herein, the term “and/or” includes any and all combinations of one or more of the associated listed items.

It is to be understood that, although the terms “first,” “second,” etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of the example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It is to be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments and is not intended to be limiting of example embodiments. As used herein, the singular forms “a,” “an,” and “the” are intended to include the plural forms as well, unless the context clearly indicates otherwise. It is to be further understood that the terms “comprises,” “comprising,” “includes,” and/or “including,” as used herein, specify the presence of stated features, integers, steps, operations, elements, and/or components, but do not preclude the presence or addition of one or more other features, integers, steps, operations, elements, components, and/or groups thereof.

Example embodiments of the inventive concepts may be described herein with reference to cross-sectional illustrations that may be schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which embodiments of the inventive concept belong. It is to be further understood that terms, such as those defined in commonly-used dictionaries, should be interpreted as having a meaning that is consistent with their meaning in the context of the relevant art and are not to be interpreted in an idealized or overly formal sense unless expressly so defined herein.

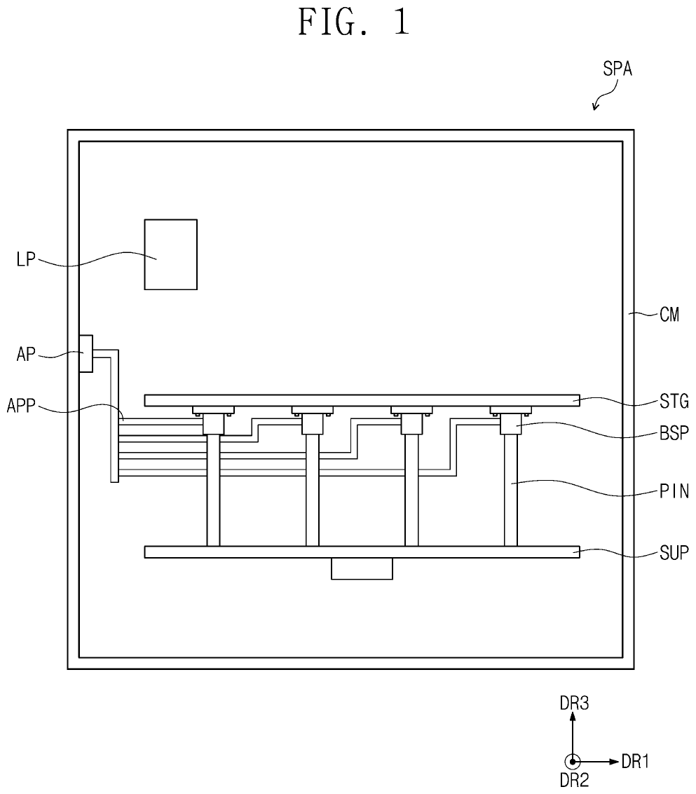

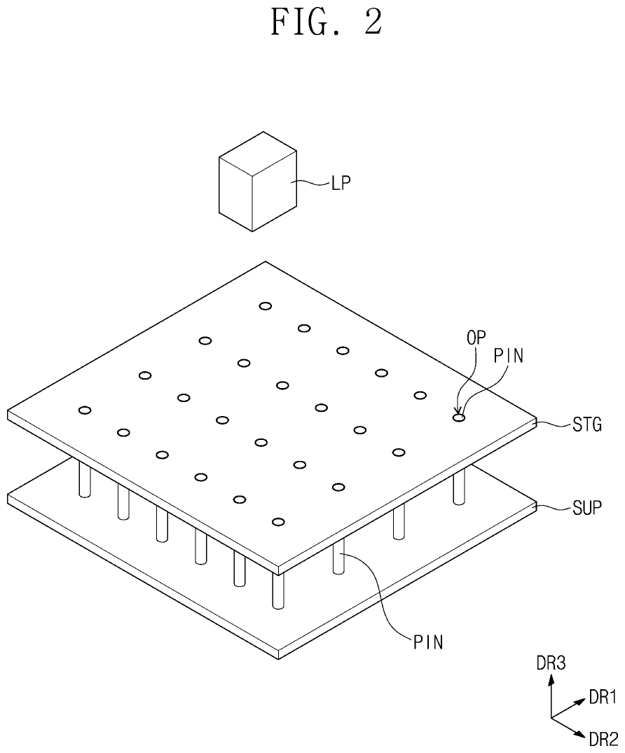

FIG. 1 is a diagram illustrating a structure of a substrate processing apparatus according to an embodiment of the inventive concept; and FIG. 2 is a perspective view illustrating a stage and a supporting part of FIG. 1.

Referring to FIGS. 1 and 2, a substrate processing apparatus SPA according to an embodiment of the inventive concept may include a process chamber CM, a stage STG, a supporting part SUP, a plurality of pins PIN, a plurality of bushing portions BSP, an air supply part AP, a plurality of air supply pipes APP, and an ultraviolet light lamp LP. The stage STG, the supporting part SUP, the pins PIN, the bushing portions BSP, the air supply part AP, the air supply pipes APP, and the ultraviolet light lamp LP may be disposed in the process chamber CM.

The stage STG may have a flat surface that is defined to be parallel to a first direction DR1 and a second direction DR2 crossing each other. In an embodiment, the stage STG may be a rectangular structure, having short sides parallel to the first direction DR1 and long sides parallel to the second direction DR2.

A plurality of openings OP may be defined in the stage STG. In an embodiment, the openings OP may be arranged in a matrix shape, but the inventive concept is not limited to this example. In an embodiment, each of the openings OP may have a circular shape.

The supporting part SUP may be disposed below the stage STG. The supporting part SUP may have a flat surface that is defined to be parallel to the first direction DR1 and the second direction DR2. In an embodiment, the supporting part SUP may be a rectangular structure, having short sides parallel to the first direction DR1 and long sides parallel to the second direction DR2. The supporting part SUP may be configured to be movable in upward and downward directions.

Herein, a direction, which is not parallel to the first and second directions DR1 and DR2, will be referred to as a third direction DR3. The third direction DR3 may be substantially perpendicular to the first and second directions DR1 and DR2. The third direction DR3 may be referred to as an upward direction.

The pins PIN may be disposed between the stage STG and the supporting part SUP. In an embodiment, the pins PIN may be arranged in a matrix shape to be overlapped with the openings OP. However, the inventive concept is not limited to this example, and the pins PIN may have any of various arrangements.

The pins PIN may be connected to the supporting part SUP and may be extended in the third direction DR3 to be disposed in the openings OP. Top ends of the pins PIN may be inserted in the openings OP. In an embodiment, each of the pins PIN may have a cylindrical shape extending in the third direction DR3.

The bushing portions BSP may be disposed below the stage STG. The bushing portions BSP may be connected to the bottom surface of the stage STG. Upper portions of the pins PIN may be inserted in the bushing portions BSP and may be disposed in the openings OP.

The ultraviolet light lamp LP may be disposed on or over the stage STG. The ultraviolet light lamp LP may be configured to produce an ultraviolet light and to emit the ultraviolet light toward the stage STG.

The air supply pipes APP may be connected to the bushing portions BSP, respectively. The air supply pipes APP may be connected in common to the air supply part AP. The air supply part AP may supply a gaseous material (e.g., the air) to the bushing portions BSP through the air supply pipes APP. For example, the air supply part AP may be supplied the air from the outside. The air may be provided to the air supply pipes APP. In an embodiment, the air may be supplied to each of the bushing portions BSP through a corresponding one of the air supply pipes APP.

In an embodiment, the air may be or include nitrogen (N₂). In an embodiment, the air may be a cooling air of 23° C. to 25° C. The cooling air may be air, which is supplied through the air supply pipes APP and flows through the bushing portions BSP. Herein, air supplied to the bushing portions BSP will be referred to as the cooling air.

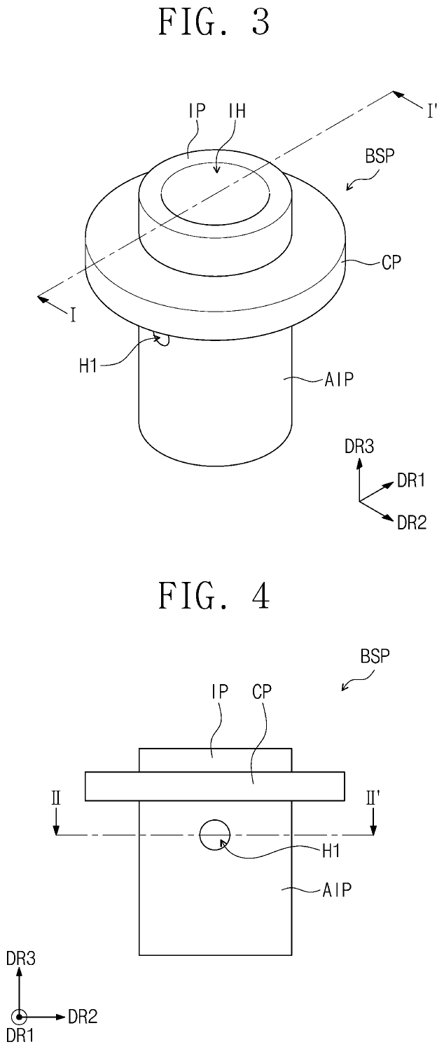

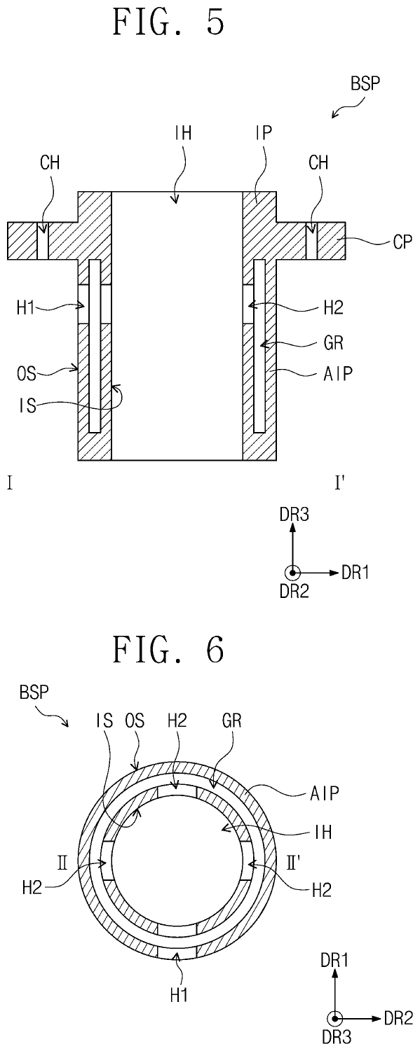

FIG. 3 is a perspective view illustrating a bushing portion of FIG. 1; and FIG. 4 is a side view of the bushing portion of FIG. 3, viewed in a first direction.

Referring to FIGS. 3 and 4, an insertion hole IH may be defined in the bushing portion BSP. The insertion hole IH may extend in the third direction DR3. For example, the insertion hole IH may be defined to pass through the bushing portion BSP in the third direction DR3. An upper portion of each of the pins PIN may be disposed in the insertion hole IH, and this structure will be described in further detail below.

The bushing portion BSP may include an insertion portion IP, a connecting portion CP, and an air injection portion AIP. The connecting portion CP may be disposed below the insertion portion IP, and the air injection portion AIP may be disposed below the connecting portion CP. Thus, the connecting portion CP may be disposed between the insertion portion IP and the air injection portion AIP.

In an embodiment, the insertion portion IP, the connecting portion CP, and the air injection portion AIP may be integrally formed. However, the inventive concept is not limited to this example, and, in another embodiment, the insertion portion IP, the connecting portion CP, and the air injection portion AIP may be separately manufactured and may be coupled to each other.

In an embodiment, each of the insertion portion IP, the connecting portion CP, and the air injection portion AIP may have a cylindrical shape extending in the third direction DR3. In other words, when viewed in the third direction DR3, each of the insertion portion IP, the connecting portion CP, and the air injection portion AIP may be circular.

In an embodiment, when viewed in the third direction DR3, the connecting portion CP may be larger than the insertion portion IP and the air injection portion AIP. For example, when measured in the first direction DR1 and the second direction DR2, the connecting portion CP may have a width or diameter larger than those of the insertion portion IP and the air injection portion AIP.

For example, when measured in the first direction DR1 and the second direction DR2, the insertion portion IP may have the same width or diameter as that of the air injection portion AIP. However, the inventive concept is not limited to this example, and the insertion portion IP and the air injection portion AIP may have widths different from each other.

In an embodiment, the air injection portion AIP may be elongated in the third direction DR3 to be longer than the insertion portion IP and the connecting portion CP. When measured in the third direction DR3, lengths of the insertion portion IP and the connecting portion CP may be substantially the same or different from each other.

A first hole H1 may be defined in the bushing portion BSP. For example, the first hole H1 may be defined in an upper portion of the air injection portion AIP. As an example, the first hole H1 may have a circular shape. The air supply pipe APP may be connected to the air injection portion AIP of the bushing portion BSP and may be used to supply the cooling air into the first hole H1.

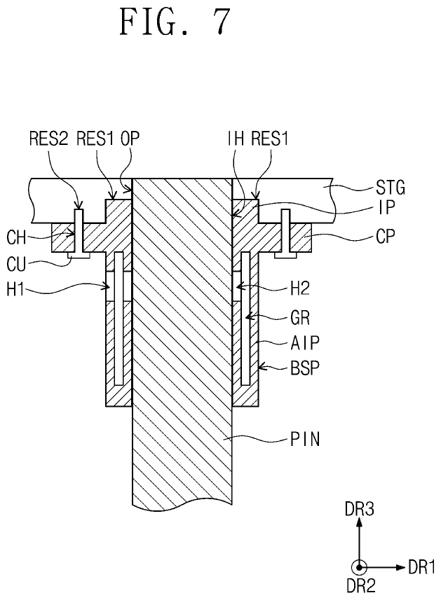

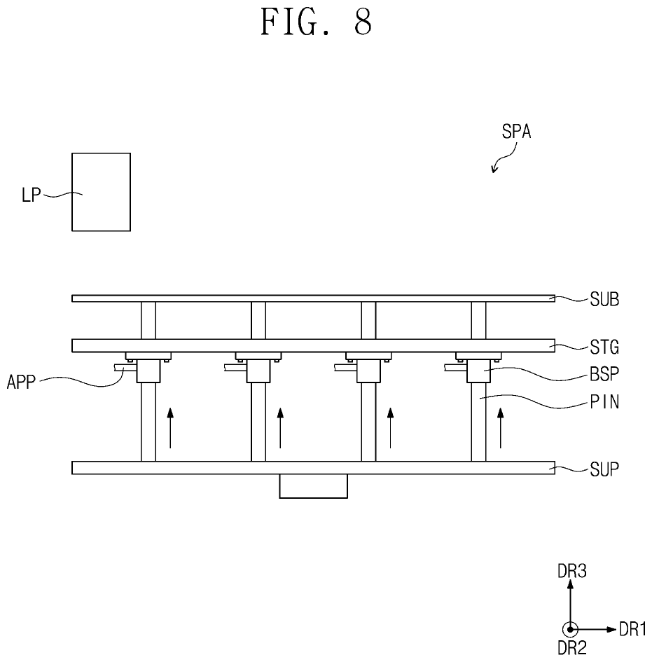

FIG. 5 is a cross-sectional view taken along the line I-I′ of FIG. 3; and FIG. 6 is a cross-sectional view taken along the line II-II′ of FIG. 4.

Referring to FIGS. 5 and 6, the insertion hole IH may be extended in the third direction DR3 and may be defined in the insertion portion IP, the connecting portion CP, and the air injection portion AIP. When viewed in the third direction DR3, the insertion hole IH may have a circular shape.

In an embodiment, a plurality of connection holes CH extending in the third direction DR3 may be defined in the connecting portion CP. Coupling units may be disposed in the connection holes CH, and the coupling units will be described in further detail below.

When viewed in the third direction DR3, the first hole H1 may be defined in an upper portion of the air injection portion AIP and may be extended toward the insertion hole IH. However, the inventive concept is not limited to this example, and the first hole H1 may be defined in any of various portions of the air injection portion AIP. For example, the first hole H1 may be defined in a middle or lower portion of the air injection portion AIP and may be extended to the insertion hole IH.

The first hole H1 may be extended to be parallel to a plane defined by the first and second directions DR1 and DR2. For example, as shown in FIGS. 5 and 6, the first hole H1 may be defined to penetrate a portion of the air injection portion AIP in the first direction DR1. Thus, the first hole H1 may be extended to the insertion hole IH in the first direction DR1.

However, the inventive concept is not limited to this example, and the first hole H1 may be defined to penetrate another portion of the air injection portion AIP in the second direction DR2. In other words, the first hole H1 may be extended to the insertion hole IH in the second direction DR2.

Although the first hole H1 is illustrated to be extended in the first direction DR1 or the second direction DR2, the extension direction of the first hole H1 is not limited thereto. For example, the first hole H1 may be extended in another direction crossing the first and second directions DR1 and DR2, on a plane defined by the first and second directions DR1 and DR2.

In an embodiment, one first hole H1 may be defined in the air injection portion AIP, as illustrated in FIG. 5, but the inventive concept is not limited to a number of the first hole H1. For example, two or more first holes H1 may be defined in the air injection portion AIP.

Since the first hole H1 is extended to the insertion hole IH, a space of the first hole H1 may be defined to be a single space that is connected to a space of the insertion hole IH. Thus, the cooling air provided into the first hole H1 may be provided into the insertion hole IH.

In an embodiment, a groove GR may be defined between an inner surface IS of the air injection portion AIP, in which the insertion hole IH is defined, and an outer surface OS of the air injection portion AIP, which is an opposite surface of the inner surface IS. The groove GR may be extended along a direction of the outer surface OS of the air injection portion AIP. Thus, when viewed in the third direction DR3, the groove GR may have a circular ring shape. A portion of the groove GR may be overlapped with the first hole H1.

A plurality of second holes H2, which are extended from the groove GR to the insertion hole IH, may be defined in the air injection portion AIP. Although three second holes H2 are illustrated as defined in the air injection portion AIP, a number of the second holes H2 is not limited to this example. The first and second holes H1 and H2 may be defined to be spaced apart from each other.

In an embodiment, the second holes H2 may extend in the first and second directions DR1 and DR2. However, the inventive concept is not limited to this example, and the second holes H2 may be extended in any of various directions crossing the first and second directions DR1 and DR2, on a plane defined by the first and second directions DR1 and DR2.

In an embodiment, the second holes H2 may be defined in an upper portion of the air injection portion AIP. For example, the second holes H2 may be defined at the same height as that of the first holes H1. However, the inventive concept is not limited to this example, and the second holes H2 may be defined at any of various portions of the air injection portion AIP. For example, the second holes H2 may be defined in a middle or lower portion of the air injection portion AIP.

In an embodiment, the groove GR may be defined to be extended from an upper portion of the air injection portion AIP to a depth lower than the first and second holes H1 and H2. For example, the groove GR may be defined from an upper portion of the air injection portion AIP higher than the first and second holes H1 and H2 to a lower portion of the air injection portion AIP lower than the first and second holes H1 and H2.

The first and second holes H1 and H2, the groove GR, and the insertion hole IH may be connected to be defined as an integral space. Thus, in the case in which the cooling air is supplied to the first hole H1, the cooling air may also be provided to the first and second holes H1 and H2, the groove GR, and the insertion hole IH.

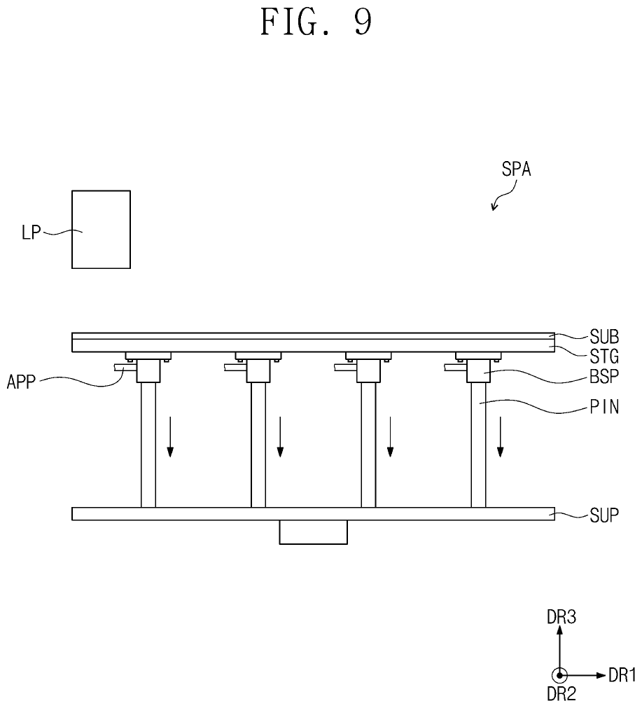

FIG. 7 is a cross-sectional view illustrating a bushing portion connected to a stage of FIG. 1 and a pin disposed in an opening.

As an example, FIG. 7 illustrates sections of the bushing portion BSP, the pin PIN, and the stage STG viewed in the second direction DR2. For convenience in illustration, one pin PIN is illustrated to be inserted in one bushing portion BSP. Others of the bushing portions BSP and the pins PIN shown in FIG. 1 may have substantially the same structure as the bushing portion BSP and the pin PIN shown in FIG. 7.

Referring to FIG. 7, a first recess RES1 may be defined in a bottom surface of the stage STG adjacent to the opening OP. The first recess RES1 may surround the opening OP. The first recess RES1 may be upwardly recessed from the bottom surface of the stage STG. The insertion portion IP may be disposed in the first recess RES1. Since the insertion portion IP is inserted into the first recess RES1, the insertion portion IP may not be exposed to the outside.

The connecting portion CP may be disposed at the bottom surface of the stage STG around the first recess RES1. The connecting portion CP may be connected to the bottom surface of the stage STG. For example, a plurality of coupling units CU may connect the connecting portion CP to the bottom surface of the stage STG. The coupling units CU may pass through the connection holes CH and may be inserted in second recesses RES2, which are defined in the bottom surface of the stage STG and are overlapped with the connection holes CH. In an embodiment, the coupling units CU may be or include screws.

The insertion hole IH may be overlapped with the opening OP and may be extended in the third direction DR3. An upper portion of the pin PIN may be inserted in the insertion hole IH and the opening OP. The pin PIN may be moved in the third direction DR3, may be first inserted into the insertion hole IH and may be inserted into the opening OP. The pin PIN may be configured to be vertically movable along the insertion hole IH and the opening OP.

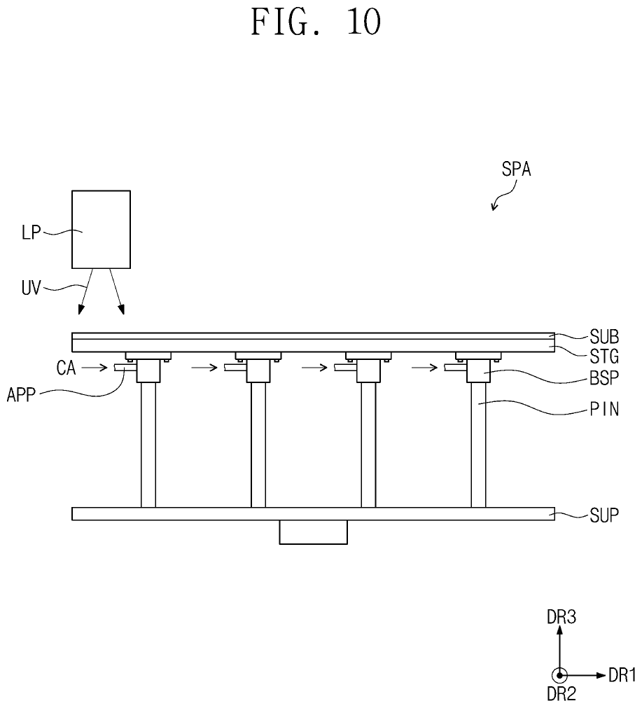

FIGS. 8 to 10 are diagrams illustrating a substrate processing process performed using the substrate processing apparatus of FIG. 1.

For convenience in illustration, the process chamber CM and the air supply part AP are omitted, and a portion of each of the air supply pipes APP connected to the bushing portions BSP is illustrated.

Referring to FIG. 8, the supporting part SUP may be moved upwardly. Although not shown, a driving part for changing a vertical position of the supporting part SUP may be connected to a bottom portion of the supporting part SUP.

The upward motion of the supporting part SUP may lead to an upward motion of the pins PIN along the insertion holes IH and the openings OP. A substrate SUB may be transported and may be loaded on the pins PIN. The substrate SUB may be supported by the pins PIN.

Referring to FIG. 9, the supporting part SUP may be moved downwardly, and the pins PIN may be downwardly moved along the insertion holes IH and the openings OP. The pins PIN may be moved downwardly, and, thus, the substrate SUB may be loaded on the stage STG.

Although not shown, an ink may be provided on the substrate SUB loaded on the stage STG. For example, an inkjet printing device may be used to eject the ink onto specific regions of the substrate SUB.

Referring to FIG. 10, an ultraviolet light UV, which is produced by the ultraviolet light lamp LP, may be irradiated onto the substrate SUB. The ultraviolet light lamp LP may irradiate the ultraviolet light UV onto the substrate SUB, while moving from a region of the substrate SUB to another region of the substrate SUB. The ink provided on the substrate SUB may be hardened or cured by the ultraviolet light UV. In an embodiment, the hardened ink on the substrate SUB may be used to form organic light emitting layers constituting the light emitting elements.

When the substrate SUB is irradiated by the ultraviolet light UV, a cooling air CA may be supplied to the bushing portions BSP through the air supply pipes APP. The cooling air CA may prevent or substantially prevent the pins PIN inserted in the bushing portions BSP from being overheated.

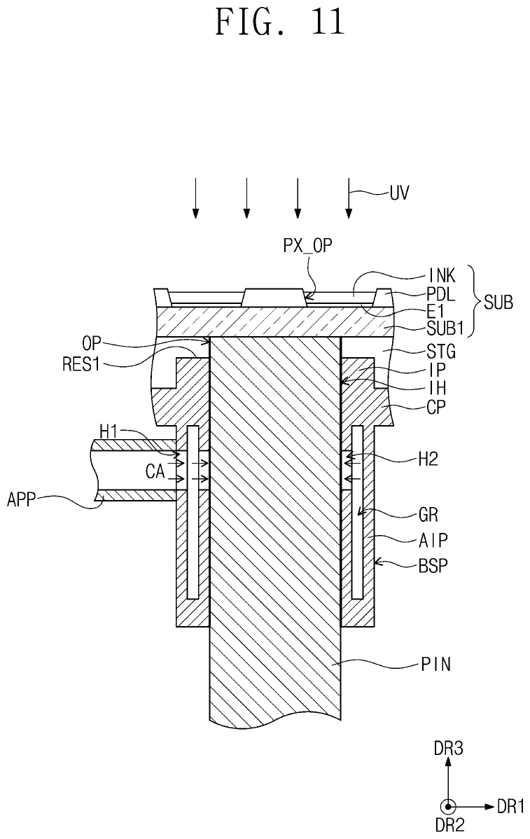

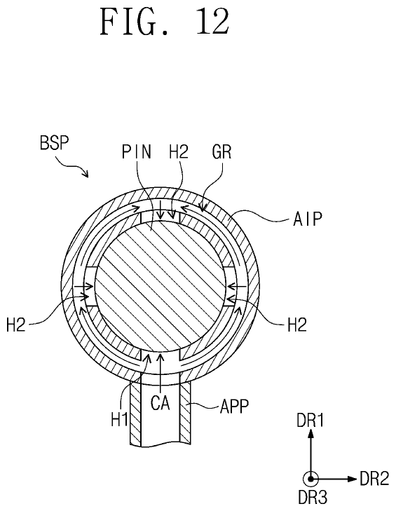

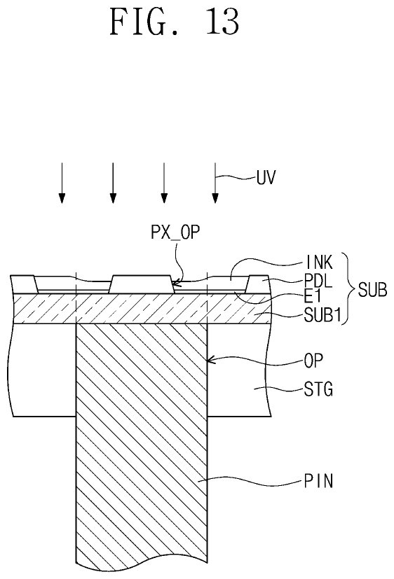

FIG. 11 is a cross-sectional view illustrating a bushing portion connected to a stage of FIG. 10, a pin disposed in an opening, and a substrate disposed on the pin. FIG. 12 is a diagram illustrating a flow of a cooling air flowing through an air injection portion of FIG. 10. FIG. 13 is a cross-sectional view illustrating a portion of a substrate processing apparatus, in which a bushing portion is not disposed.

For convenience in illustration, a cross-section of the bushing portion corresponding to FIG. 7 is illustrated in FIG. 11, but the coupling units CU are omitted from FIG. 11. FIG. 12 illustrates a cross-section of the bushing portion corresponding to FIG. 6.

Referring to FIG. 11, the substrate SUB may be disposed on the stage STG and the pin PIN. A top end of the pin PIN may be in contact with the bottom surface of the substrate SUB.

In an embodiment, the substrate SUB may include a first substrate SUB1, a pixel definition layer PDL provided on the first substrate SUB1, a first electrode E1, which is disposed in each of pixel openings PX_OP defined in the pixel definition layer PDL, and an ink INK, which is disposed on the first electrode E1 in each of the pixel openings PX_OP. In the case in which the ultraviolet light UV is irradiated onto the ink INK, the ink INK may be hardened to form an organic light emitting layer.

The air supply pipe APP may be connected to a portion of the air injection portion AIP around the first hole H1. The air supply pipe APP may supply the cooling air CA to the first hole H1. The cooling air CA supplied to the first hole H1 may be provided to the insertion hole IH through the first hole H1. The cooling air CA may be provided to an upper portion of the pin PIN disposed in the insertion hole IH. The upper portion of the pin PIN may be defined as a portion of the pin PIN that is located adjacent to the substrate SUB.

Referring to FIG. 12, the cooling air CA supplied to the first hole H1 may be moved along the groove GR and may be provided to the second holes H2. The cooling air CA may be provided into the insertion hole IH through the second holes H2. Thus, the cooling air CA may be provided to the pin PIN, which is disposed in the insertion hole IH, through the first and second holes H1 and H2. Thus, the pin PIN may be cooled by the cooling air CA.

Referring to FIG. 13, the substrate SUB may be disposed on the stage STG, and the top end of the pin PIN disposed in the opening OP may be in contact with the bottom surface of the substrate SUB. The ultraviolet light UV may be provided to the ink INK on the substrate SUB.

Due to the energy supplied by the ultraviolet light UV, the pin PIN may be heated to have a temperature higher than those of the substrate SUB and the stage STG. Thus, there may be a difference in temperature between the pin PIN and the substrate SUB. In the case in which the top end of the pin PIN is in contact with the bottom surface of the substrate SUB, the difference in temperature between the pin PIN and the substrate SUB may cause a stain issue on the substrate SUB.

For example, when viewed in the third direction DR3, a portion of the ink INK overlapped with the pin PIN may be dislodged from the region of the pin PIN by the heated pin PIN. In this case, the organic light emitting layers, which are formed by hardening the ink INK, may have a height difference. The organic light emitting layers with the height difference may be recognized as a stain on the substrate SUB. That is, defects may occur on the substrate SUB.

Referring to FIGS. 11 and 12, according to an embodiment of the inventive concept, the cooling air CA may be supplied to the bushing portion BSP and may be provided to the upper portion of the pin PIN through the first and second holes H1 and H2 of the bushing portion BSP. Thus, it may be possible to prevent the pin PIN from being overheated and to reduce a difference in temperature between the substrate SUB and the pin PIN. Accordingly, it may be possible to prevent the stain issue from occurring on the substrate SUB by the pin PIN.

According to an embodiment of the inventive concept, the substrate processing apparatus SPA may be configured to cool the pins PIN, and this may make it possible to prevent the stain issue from occurring on the substrate SUB.

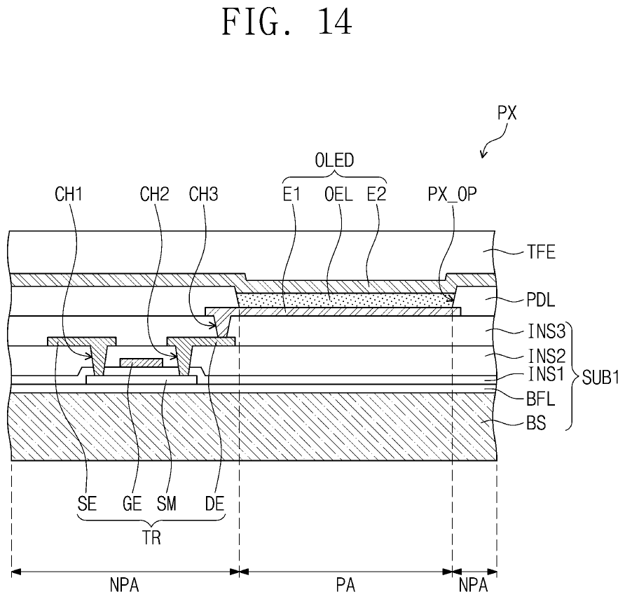

FIG. 14 is a cross-sectional view illustrating a pixel including an organic light emitting layer, which is fabricated by a substrate processing apparatus according to an embodiment of the inventive concept.

Referring to FIG. 14, a pixel PX may include a light emitting element OLED and a transistor TR connected to the light emitting element OLED. The light emitting element OLED may be an organic light emitting element. The light emitting element OLED may include a first electrode E1, an organic light emitting layer OEL, and a second electrode E2.

The transistor TR and the light emitting element OLED may be disposed on a base substrate BS. The base substrate BS may be a transparent flexible substrate. For example, the base substrate BS may include a flexible plastic material, such as polyimide (PI). A buffer layer BFL may be provided on the base substrate BS and may be formed of or include an inorganic material.

A semiconductor layer SM of the transistor TR may be disposed on the buffer layer BFL. The semiconductor layer SM may be formed of or include an inorganic semiconductor material (e.g., amorphous silicon or poly silicon) or an organic semiconductor material. In addition, the semiconductor layer SM may be formed of or include an oxide semiconductor material. Although not shown in FIG. 14, the semiconductor layer SM may include a source region, a drain region, and a channel region between the source region and the drain region.

A first insulating layer INS1 may be disposed on the buffer layer BFL to cover the semiconductor layer SM. The first insulating layer INS1 may be formed of or include an inorganic material. The transistor TR may include a gate electrode GE, which is provided on the first insulating layer INS1 and is overlapped with the semiconductor layer SM. The gate electrode GE may be disposed to be overlapped with the channel region of the semiconductor layer SM.

A second insulating layer INS2 may be disposed on the first insulating layer INS1 to cover the gate electrode GE. The second insulating layer INS2 may be defined as an interlayer insulating layer. The second insulating layer INS2 may be formed of or include an organic material and/or an inorganic material.

The transistor TR may include a source electrode SE and a drain electrode DE, which are provided on the second insulating layer INS2 and are spaced apart from each other. The source electrode SE may be connected to the source region of the semiconductor layer SM through a first contact hole CH1, which is formed to penetrate the first insulating layer INS1 and the second insulating layer INS2. The drain electrode DE may be connected to the drain region of the semiconductor layer SM through a second contact hole CH2, which is formed to penetrate the first insulating layer INS1 and the second insulating layer INS2.

A third insulating layer INS3 may be disposed on the second insulating layer INS2 to cover the source electrode SE and the drain electrode DE of the transistor TR. The third insulating layer INS3 may be defined as a planarization layer providing a flat top surface and may be formed of or include an organic material. Layers from the base substrate BS to the third insulating layer INS3 may be defined as the first substrate SUB1.

The first electrode E1 of the light emitting element OLED may be disposed on the third insulating layer INS3. The first electrode E1 may be connected to the drain electrode DE of the transistor TR through a third contact hole CH3, which is formed to penetrate the third insulating layer INS3. The first electrode E1 may be defined as a pixel electrode or an anode electrode. The first electrode E1 may be formed of or include a transparent material or a reflective material.

The pixel definition layer PDL may be disposed on the first electrode E1 and the third insulating layer INS3 to expose a portion of the first electrode E1. The pixel definition layer PDL may be provided to define a pixel opening PX_OP exposing a specific portion of the first electrode E1. A region provided with the pixel opening PX_OP may be defined as a pixel region PA. A region around the pixel region PA may be defined as a non-pixel region NPA.

The organic light emitting layer OEL may be disposed in the pixel opening PX_OP and on the first electrode E1. As described above, the organic light emitting layer OEL may be formed by hardening or curing the ink INK. In an embodiment, the organic light emitting layer OEL may include an organic material capable of generating one of red, green, and blue lights, and the organic light emitting layer OEL may generate one of red, green, and blue lights. However, the inventive concept is not limited to this example, and the organic light emitting layer OEL may include a mixture of organic materials capable of generating red, green, and blue lights and may be configured to generate white light.

The second electrode E2 may be disposed on the pixel definition layer PDL and the organic light emitting layer OEL. The second electrode E2 may be defined as a common electrode or a cathode electrode. The second electrode E2 may be formed of or include a transparent material or a reflective material.

In the case in which the pixel PX is of a top emission type, the first electrode E1 may be formed of a reflective material, and the second electrode E2 may be formed of a transparent material. In the case in which the pixel PX is of a bottom emission type, the first electrode E1 may be formed of a transparent material, and the second electrode E2 may be formed of a reflective electrode.

A thin encapsulation layer (e.g., a thin film encapsulation layer) TFE may be disposed on the light emitting element OLED. The thin encapsulation layer TFE may be formed of or include an organic material and/or an inorganic material.

For light emission of the organic light emitting layer OEL, a first voltage may be applied to the first electrode E1, for example, through the transistor TR, and a second voltage, which has a sign or polarization opposite to the first voltage, may be applied to the second electrode E2. In the case in which holes and electrons are injected into the organic light emitting layer OEL, excitons may be produced. Light may be emitted from the light emitting element OLED when the excitons are transitioned to a ground state. The light emitting element OLED may emit red, green, or blue light, which constitutes an image to be seen by a user, by using a current flowing therethrough.

A substrate processing apparatus according to embodiments of the inventive concept may include bushing portions, which are disposed on pins adjacent to a substrate and are used to provide cooling air to the pins and to cool the pins. Thus, the pins may be prevented from being overheated and a difference in temperature between the substrate and the pins may be reduced. Accordingly, a substrate stain issue may be prevented or substantially prevented from occurring by the pins.

While some example embodiments of the inventive concepts have been particularly shown and described, it will be understood by one of ordinary skill in the art that variations in form and detail may be made therein without departing from the spirit and scope of inventive concept, as set forth in the attached claims.

What is claimed is:

1. A substrate processing apparatus, comprising:
a stage having a plane defined by a first direction and a second direction crossing each other;
a pin arranged in an opening defined in the stage and extending in a third direction crossing the plane; and
a bushing portion below the stage,
wherein the pin is inserted in an insertion hole defined in the bushing portion, the insertion hole overlaps with the opening, and a first hole extending to the insertion hole in a direction parallel to the plane is defined in the bushing portion.

2. The substrate processing apparatus of claim 1, wherein air is provided to an upper portion of the pin that is in the insertion hole, through the first hole.

3. The substrate processing apparatus of claim 2, further comprising an air supply pipe connected to the bushing portion to supply the air to the first hole.

4. The substrate processing apparatus of claim 1, wherein the bushing portion comprises:
an insertion portion in a first recess defined in a bottom surface of the stage adjacent to the opening;
a connecting portion below the insertion portion and connected to a bottom surface of the stage around the first recess; and
an air injection portion below the connecting portion and extending in the third direction, the first hole being defined in the air injection portion,
wherein the insertion hole is defined to penetrate the insertion portion, the connecting portion, and the air injection portion in the third direction.

5. The substrate processing apparatus of claim 4, wherein, when measured in the first and second directions, the connecting portion has a width larger than widths of the insertion portion and the air injection portion, and
the air injection portion extends in the third direction to be longer than the insertion portion and the air injection portion.

6. The substrate processing apparatus of claim 4, wherein the insertion portion, the connecting portion, and the air injection portion have a cylindrical shape extending in the third direction.

7. The substrate processing apparatus of claim 4, further comprising a plurality of coupling units connecting the connecting portion to the stage.

8. The substrate processing apparatus of claim 4, wherein a groove is defined between an inner surface of the air injection portion defining the insertion hole and an outer surface of the air injection portion opposite to the inner surface, and
when viewed in the third direction, the groove has a ring shape and includes a portion overlapping with the first hole.

9. The substrate processing apparatus of claim 8, wherein a plurality of second holes extending from the groove to the insertion hole are defined in the air injection portion.

10. The substrate processing apparatus of claim 9, wherein the first and second holes are defined in an upper portion of the air injection portion.

11. The substrate processing apparatus of claim 9, wherein the groove is defined from an upper portion of the air injection portion higher than the first and second holes to a lower portion of the air injection portion lower than the first and second holes.

12. The substrate processing apparatus of claim 4, wherein the insertion portion, the connecting portion, and the air injection portion are integrally formed.

13. The substrate processing apparatus of claim 1, wherein a substrate is configured to be arranged on the pin, and the pin is vertically movable along the opening and the insertion hole.

14. The substrate processing apparatus of claim 13, further comprising an ultraviolet light lamp over the substrate and configured to irradiate ultraviolet light onto the substrate and to harden ink provided on the substrate.

15. A bushing portion, comprising:
an insertion portion;
a connecting portion below the insertion portion; and
an air injection portion below the connecting portion and in which an insertion hole extending in an upward direction is defined,
wherein the upward direction crosses a plane defined by a first direction and a second direction crossing each other,
the insertion hole extends in the upward direction and is defined in the connecting portion and the insertion portion,
a first hole extending to the insertion hole in a direction parallel to the plane is defined in the air injection portion, and
the first hole is configured to be supplied with cooling air.

16. The bushing portion of claim 15, wherein, when measured in the first and second directions, the connecting portion has a width larger than widths of the insertion portion and the air injection portion, and
the air injection portion extends in the upward direction to be longer than the insertion portion and the air injection portion.

17. The bushing portion of claim 15, wherein a groove is defined between an inner surface of the air injection portion defining the insertion hole and an outer surface of the air injection portion opposite to the inner surface, and
when viewed in the upward direction, the groove has a ring shape and includes a portion overlapping with the first hole.

18. The bushing portion of claim 17, wherein a plurality of second holes extending from the groove to the insertion hole are defined in the air injection portion.

19. The bushing portion of claim 18, wherein the first and second holes are defined in an upper portion of the air injection portion, and
the first and second holes, the groove, and the insertion hole are defined as an integral space.

20. The bushing portion of claim 18, wherein the groove is defined from an upper portion of the air injection portion higher than the first and second holes to a lower portion of the air injection portion lower than the first and second holes.
